(19) United States
(12) Patent Application Publication
(10) Pub. No.: US 2025/0374627 A1
(43) Pub. Date: Dec. 4, 2025

(54) SEMICONDUCTOR DEVICE AND METHOD FOR FORMING THE SAME

(71) Applicant: Vanguard International Semiconductor Corporation, Hsinchu (TW)

(72) Inventors: Wen-Shan LEE, Hsinchu City (TW); Chung-Yeh LEE, Xinpu Township (TW); Fu-Hsin CHEN, Zhudong Township (TW)

(73) Assignee: Vanguard International Semiconductor Corporation, Hsinchu (TW)

(21) Appl. No.: 18/680,081

(22) Filed: May 31, 2024

(51) Int. Cl. H01L 29/16; H01L 29/06; H01L 29/40; H01L 29/66; H01L 29/78

(52) U.S. Cl. CPC H10D 62/8325; H10D 12/031; H10D 30/0297; H10D 30/668; H10D 62/127; H10D 64/111

(57) ABSTRACT

A semiconductor device and a method for forming the same are provided. The semiconductor device includes a silicon carbide substrate, an epitaxial layer, a first electrode, a split-gate structure and a source contact. The epitaxial layer is disposed on a top surface of the silicon carbide substrate. The silicon carbide substrate and the epitaxial layer have a first conductivity type. The first electrode is disposed in the epitaxial layer in the first region and extends along a first direction. The split-gate structure includes a first gate electrode and a second gate electrode located on opposite side walls of the first electrode. A top portion of the first electrode is exposed from the split-gate structure. The source contact is disposed on the epitaxial layer in the first region. The source contact covers and is electrically connected to the top of the first electrode.

### BACKGROUND OF THE INVENTION

### Field of the Invention

The present disclosure relates to a semiconductor device and a method for forming the same, and, in particular, to a power transistor device having a self-aligned contact feature and a method for forming the same.

### Description of the Related Art

The semiconductor industry continues to improve the integration density of different electronic components, thereby allowing more components to be integrated in a given area by continuing to reduce the minimum component size. For example, trench gate metal-oxide-semiconductor field effect transistors (MOSFETs), which are widely used in power switches, use a vertical structure design to increase functional density by reducing cell pitch. A trench gate MOSFET uses the back side of the chip as a drain electrode, and forms the source electrodes and the gate electrodes of multiple transistors on the front side of the chip. Therefore, the driving current flows from the horizontal direction to the vertical direction. A trench gate MOSFET also enables the semiconductor device to achieve a high reverse withstand voltage and low on-resistance.

However, as the functional density requirements on semiconductor devices continue to increase, the complexity of integrated components in the semiconductor devices and methods for forming semiconductor devices also increases. In addition, those electronic characteristics that have performance trade-offs need careful consideration. Although existing semiconductor devices are generally suitable and sufficient for their intended purposes, they have not been entirely satisfactory in all respects.

### BRIEF SUMMARY OF THE INVENTION

An embodiment of the disclosure provides a semiconductor device. The semiconductor device includes a silicon carbide substrate, an epitaxial layer, a first electrode, a split gate structure and a source contact. The silicon carbide substrate has a first region, a second region and a third region, and has a first conductivity type. The epitaxial layer is disposed on a top surface of the silicon carbide substrate. The epitaxial layer has a first conductivity type. The first electrode is disposed in the epitaxial layer in the first region and extends in the first direction. The split gate structure is disposed in the epitaxial layer in the first region. The split gate structure includes a first gate electrode and a second gate electrode separated from each other, located on opposite sidewalls of the first electrode and extending in the first direction. A top portion of the first electrode is exposed from the split gate structure. The source contact is disposed on the epitaxial layer in the first region. The source contact covers and is electrically connected to the top portion of the first electrode.

Another embodiment of the disclosure provides a method for forming a semiconductor device. A method for forming a semiconductor device includes providing a silicon carbide substrate. The silicon carbide has a first region, a second region and a third region, and the silicon carbide has a first conductivity type. The method further includes growing an epitaxial layer on a top surface of the silicon carbide substrate. The epitaxial layer has a first conductivity type. The method further includes forming a first trench in the epitaxial layer of the first region along a first direction. The method further includes forming a first electrode in the first trench. The first electrode extends in the first direction. The method further includes forming a first gate electrode and a second gate electrode separated from each other on opposite sidewalls of the first electrode. The method further includes entirely forming an interlayer dielectric layer completely removing the interlayer dielectric layer on a top surface of the epitaxial layer in the first region. A top portion of the first electrode is exposed from the remaining interlayer dielectric layer. The method further includes forming a source contact on the epitaxial layer in the first region. The source contact covers and is electrically connected to the top portion of the first electrode.

### BRIEF DESCRIPTION OF THE DRAWINGS

The present invention can be more fully understood by reading the subsequent detailed description and examples with references made to the accompanying drawings, wherein:

FIG. 1 is a schematic cross-sectional view of a semiconductor device in accordance with some embodiments of the disclosure; and

FIGS. 2, 3, 4, 5, 6, 7, 8, 9, 10, 11, 12, 13, 14, 15, 16, 17, 18, and 19 are schematic cross-sectional views of intermediate stages of forming the semiconductor device of FIG. 1 in accordance with some embodiments of the disclosure; and

FIG. 20 is a schematic top view of an intermediate stage of forming the semiconductor device of FIG. 1 in accordance with some embodiments of the disclosure, showing the arrangement of the source region and the pick-up doped region located on the well region.

### DETAILED DESCRIPTION OF THE INVENTION

The embodiments of the present disclosure are described fully hereinafter with reference to the accompanying drawings. It should be noted, however, that the present disclosure is not limited to the following exemplary embodiments, and may be implemented in various forms. Also, the drawings as illustrated are only schematic and are non-limiting. In the drawings, the size of some of the elements may be exaggerated for illustrative purposes and not drawn to scale. The dimensions and the relative dimensions do not correspond to actual dimensions in the practice of the disclosure.

The following disclosure provides various embodiments, or examples, for implementing different features of the subject matter provided. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In high-density shielded gate trench metal-oxide-semiconductor field-effect transistor (SGT MOSFET) cell arrays, expensive high-resolution masks (such as deep ultraviolet (DUV) masks) and photolithography processes are required to form source contacts between adjacent transistor units. However, during the conventional source contact processes, photoresist rework problem often occurs due to the contact-to-trench overlay error. Therefore, the fabrication cost and manufacturing cycle time are increased. Moreover, the contact-to-trench overlay error will cause the variation of the electrical parameters of adjacent transistor units, thereby causing the failure during device reliability tests (for example, UIS (Unclamped Inductive Switching) electrical tests. The contact-to-trench overlay error may further cause the burnout problem of the components. Therefore, a novel semiconductor device such as a shielded gate trench metal-oxide-semiconductor field-effect transistor (SGT MOSFET) and a method for forming the same are desired to solve or improve the abovementioned problems.

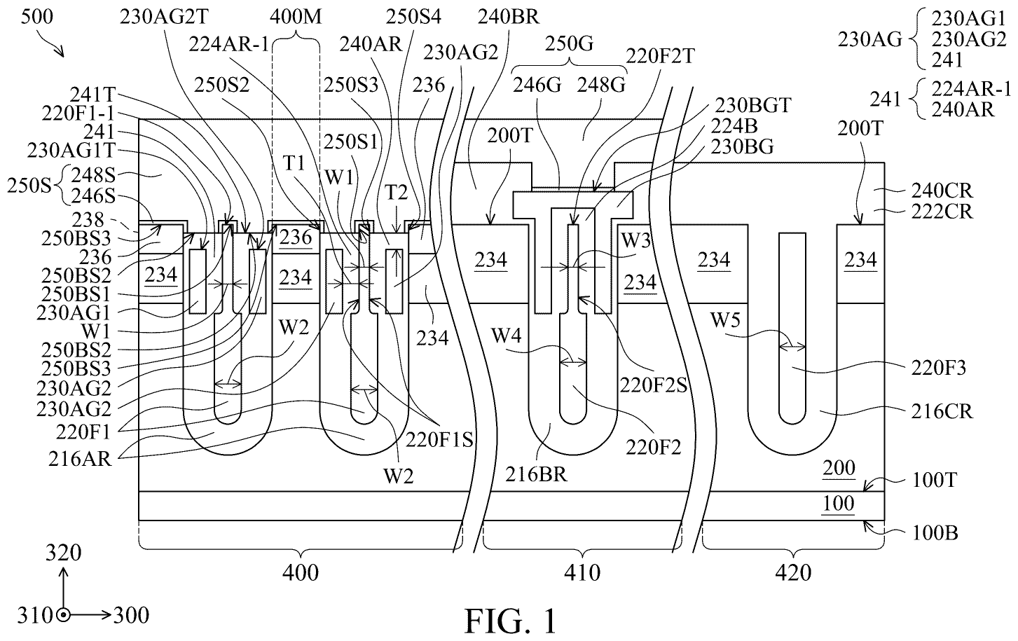

FIG. 1 is a schematic cross-sectional view of a semiconductor device 500 in accordance with some embodiments of the disclosure. In some embodiments, the semiconductor device 500 includes a power metal-oxide-semiconductor field-effect transistor (power MOSFET), such as a shielded gate trench metal-oxide-semiconductor field-effect transistor (SGT MOSFET) having a split-gate structure. As shown in FIG. 1, the semiconductor device 500 includes a silicon carbide (SiC) substrate 100, an epitaxial layer 200, a split gate structure 230AG, and a source contact 250S. In FIG. 1 and the following figures, directions 300 and 310 are directions that are substantially parallel to a top surface 100T of the silicon carbide substrate 100 and may also serve as lateral directions. The direction 320 is the direction that is substantially perpendicular to the top surface 100T of the silicon carbide substrate 100 and may also serve as the longitudinal (vertical) direction (or may serve as the channel length direction). Moreover, the direction 300 is perpendicular to the directions 310 and 320, the direction 310 is perpendicular to the directions 300 and 320, and the direction 320 is perpendicular to the directions 300 and 310.

As shown in FIG. 1, the silicon carbide substrate 100 has a top surface 100T and a bottom surface 100B. Furthermore, the silicon carbide substrate 100 has a first region 400, a second region 410, and a third region 420. In some embodiments, the first region 400 may be a cell region providing a power metal-oxide-semiconductor field-effect transistor array formed within. The second region 410 may be a gate pickup region providing a gate contacts formed thereon. In addition, the third region 420 may be a termination region, which is used to surround the cell region and serve as a buffer region for a doping region in the cell region to avoid a sudden drop in the device breakdown voltage at the boundary of the cell region. In the following embodiments, two shielded gate trench metal-oxide-semiconductor field-effect transistor units are used as an example for the structural description in the cell region (the first region 400). Furthermore, one trench electrode (for example, a source electrode) is used as an example for the structural description in the gate pickup region (the second region 410) and the terminal region (the third region 420). However, any number of shielded gate trench metal-oxide-semiconductor field-effect transistor units and trench electrodes may be disposed in the cell region, the gate pickup region, and the terminal region, and are not limited to the disclosed embodiments.

In some embodiments, the conductivity type of the silicon carbide substrate 100 may be P-type or N-type according to design requirements of the products. In this embodiment, the silicon carbide substrate 100 may be doped with dopants to have a first conductivity type, such as N-type. In the applications of vertical trench-gate metal-oxide-semiconductor field-effect transistors (vertical trench-gate MOSFETs), the silicon carbide substrate 100 having the first conductivity type may be used as a drain region of the resulting semiconductor device 500.

The epitaxial layer 200 is disposed on the top surface 100T of the silicon carbide substrate 100. In some embodiments, the epitaxial layer 200 may be doped with dopants to have the first conductivity type. For example, when the silicon carbide substrate 100 is an N-type silicon carbide substrate 100, the epitaxial layer 200 is an N-type epitaxial layer 200. Moreover, the doping concentration of the epitaxial layer 200 (for example, about 10¹⁵-10¹⁶ atoms/cm³) is lighter than the doping concentration of the silicon carbide substrate 100 (for example, about 10¹⁹-10²¹ atoms/cm³). For example, when the silicon carbide substrate 100 is an N-type heavily doped (N+) silicon carbide substrate 100, the epitaxial layer 200 is an N− type lightly doped (N−) epitaxial layer 200. In the applications of vertical trench-gate metal-oxide-semiconductor field-effect transistor (the vertical trench-gate MOSFET), the epitaxial layer 200 having the first conductivity type may serve as a drift region of the resulting semiconductor device 500. In some embodiments, the epitaxial layer 200 includes silicon carbide.

The well region 234 of the semiconductor device 500 is located in the epitaxial layer 200 in the first region 400, the second region 410, and the third region 420, and is close to a top surface 200T of the epitaxial layer 200. In some embodiments, the well region 234 may be doped with dopants to have a second conductivity type that is opposite to the first conductivity type. For example, when the silicon carbide substrate 100 is an N-type silicon carbide substrate 100, the well region 234 is a P-type well region 234. Furthermore, the dopant having the second conductivity type may include aluminum (Al), boron (B) or other suitable dopants. In some embodiments, the doping concentration of the well region 234 (e.g., about 10¹⁷-10¹⁸ atoms/cm³) is greater than the doping concentration of the epitaxial layer 200. In some embodiments, an ion implantation process may be used to form the well region 234. In the applications of vertical trench gate metal-oxide-semiconductor field-effect transistors, the well region 234 having the second conductivity type may serve as a channel region of the resulting semiconductor device 500.

The source region 236 of the semiconductor device 500 is located on the well region 234 in the first region 400 and is close to the top surface 200T of the epitaxial layer 200. Furthermore, the source region 236 may not be included in the second region 410 and the third region 420. As shown in FIG. 1, the source region 236 is surrounded by the well region 234. In some embodiments, the source region 236 may be doped with dopants to have the first conductivity type. For example, when the silicon carbide substrate 100 is an N-type silicon carbide substrate 100, the source region 236 is an N-type source region 236. Furthermore, the doping concentration of the source region 236 is greater than the doping concentration of the epitaxial layer 200. For example, when the epitaxial layer 200 is an N-type lightly doped (N−) epitaxial layer 200, the source region 236 is an N-type heavily doped (N+) source region 236.

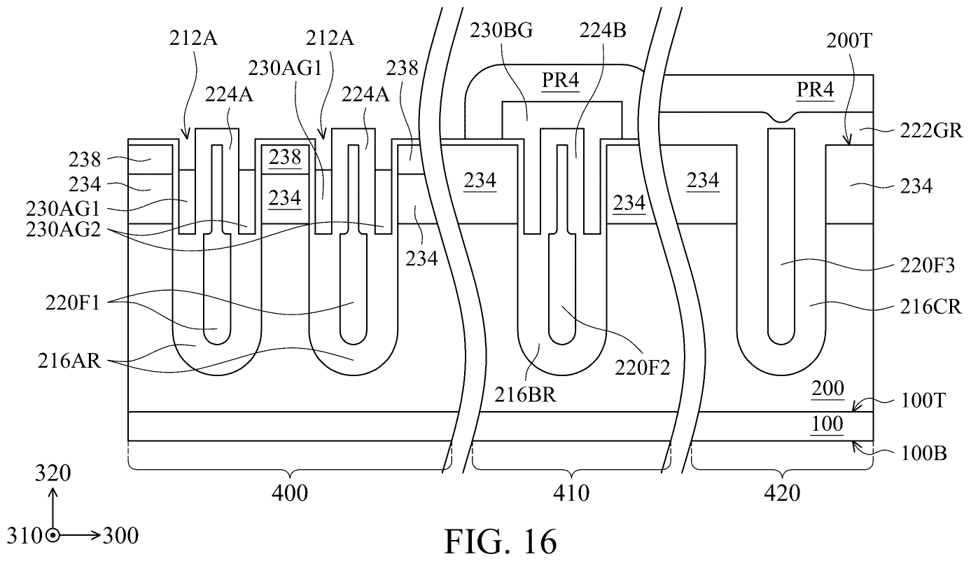

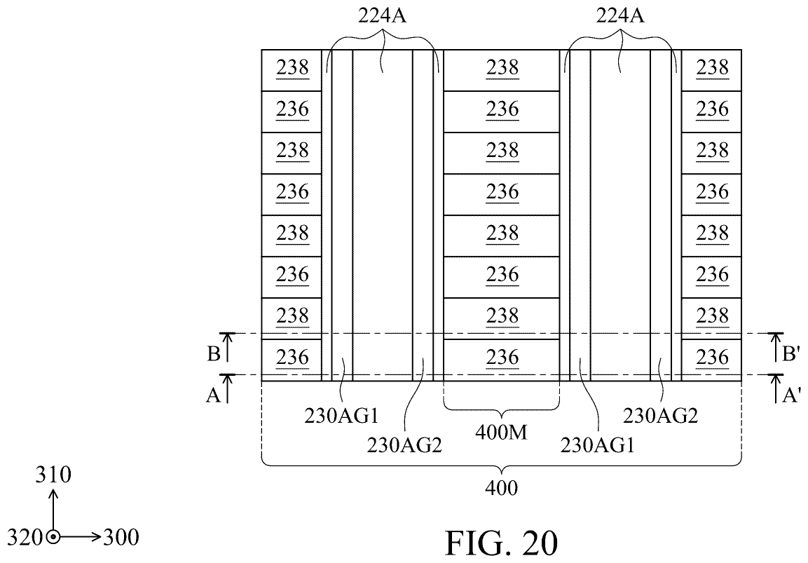

The semiconductor device 500 further includes a pick-up doped region 238 (FIGS. 16 and 20). The pick-up doped region 238 is located on the well region 234 in the first region 400 and is close to the top surface 200T of the epitaxial layer 200. Furthermore, the pick-up doped region 238 may not be included in the second region 410 and the third region 420. As shown in FIG. 16, the pick-up doped region 238 is surrounded by the well region 234. The source region 236 and the pick-up doped region 238 are adjacent to each other in the direction 310. Moreover, in some embodiments, the source regions 236 and the pick-up doped regions 238 are alternately arranged in the direction 310. The source region 236 and the pick-up doped region 238 may have opposite conductivity types. For example, when the source region 236 has a first conductivity type, the pick-up doped region 238 has a second conductivity type. The pick-up doped region 238 and the well region 234 may have the same conductivity type. For example, the pick-up doped region 238 may serve as the P-type pick-up doped region 238. Furthermore, the doping concentration of the pick-up doped region 238 is greater than the doping concentration of the well region 234. For example, when the well region 234 is a P-type well region 234, the pick-up doped region 238 is a P-type heavily doped (P+) pick-up doped region 238 to serve as the pick-up doped region of the well region 234.

The semiconductor device 500 further includes shielding dielectric layers 216AR, 216BR, 216CR, a first electrode 220F1, a second electrode 220F2, and a third electrode 220F3. As shown in FIG. 1, the shielding dielectric layer 216AR and the first electrode 220F1 are disposed in the epitaxial layer 200 of the first region 400. The shielding dielectric layer 216AR may be located below the top surface 200T of the epitaxial layer 200. The first electrode 220F1 is located on the shielding dielectric layer 216AR, and the shielding dielectric layer 216AR may cover the bottom surface and the opposite sidewalls of the first electrode 220F1. As shown in FIG. 1, the first electrode 220F1 may extend in the direction 320 toward the top surface 200T of the epitaxial layer 200 and the silicon carbide substrate 100. Moreover, a top portion 220F1-1 of the first electrode 220F1 is exposed from the split gate structure 230AG. In some embodiments, in the direction 300, a width W1 of an upper portion of the first electrode 220F1 (including the top portion 220F1-1) is less than a width W2 of a lower portion of the first electrode 220F1.

As shown in FIG. 1, the shielding dielectric layer 216BR and the second electrode 220F2 are disposed in the epitaxial layer 200 in the second region 410. The second electrode 220F2 extends from a position close to the top surface 200T of the epitaxial layer 200 toward to the silicon carbide substrate 100 along the direction 320. The second electrode 220F2 is located on the shielding dielectric layer 216BR. In addition, the shielding dielectric layer 216BR covers a bottom surface and opposite sidewalls of the second electrode 220F2. In some embodiments, in the direction 300, a width W3 of the upper portion of the second electrode 220F2 is less than a width W4 of the lower portion of the second electrode 220F2. In some embodiments, the width W1 may be equal to the width W3, In addition, the width W2 may be equal to the width W4.

As shown in FIG. 1, the shielding dielectric layer 216CR and the third electrode 220F3 are disposed in the epitaxial layer 200 in the third region 420. The third electrode 220F3 extends from a position close to the top surface 200T of the epitaxial layer 200 toward the silicon carbide substrate 100 along the direction 320. The third electrode 220F3 is located on the shielding dielectric layer 216CR. In addition, the shielding dielectric layer 216CR covers a bottom surface and opposite sidewall of the third electrode 220F3. In some embodiments, in the direction 300, third electrode 220F3 has a uniform width W5. In some embodiments, the width W5 may be equal to the widths W1, W3.

In some embodiments, shielding dielectric layers 216AR, 216BR and 216CR may include the same material. For example, the shielding dielectric layers 216AR, 216BR and 216CR may include silicon oxide, other suitable semiconductor oxide materials, or a combination thereof. In some embodiments, the shielding dielectric layers 216AR, 216BR and 216CR may be formed using a conformably deposition process, an oxidation process, or another suitable process. In some embodiments, the oxidation process may be thermal oxidation or another suitable process. In some embodiments, the deposition process may be a physical vapor deposition (PVD) process, a chemical vapor deposition (CVD) process, a plasma-enhanced chemical vapor deposition (PECVD) process, another suitable process, or a combination thereof.

In some embodiments, the first electrode 220F1, the second electrode 220F2, and the third electrode 220F3 may optionally include a dopant of the second conductivity type. For example, when the silicon carbide substrate 100 is an N-type silicon carbide substrate 100, the first electrode 220F1, the second electrode 220F2, and the third electrode 220F3 are respectively a P-type first electrode 220F1, a P-type second electrode 220F2, and a P-type third electrode 220F3. Furthermore, the dopant having the second conductivity type may include aluminum (Al), boron (B), boron difluoride (BF₂) or other suitable dopants. In some embodiments, the first electrode 220F1, the second electrode 220F2, and the third electrode 220F3 are electrically connected to the source contact 250S.

In some embodiments, the first electrode 220F1 may reduce the gate-to-drain capacitance (C_{gd}) to improve the switching characteristics of the semiconductor device 500. In addition, the first electrode 220F1 has a function of a field plate, such that the distribution of the electric field of the gate dielectric layer close to the bottom of the gate electrode 230AG (such as a gate dielectric layer 241 shown in FIG. 1, which will be described below) is relatively uniform and the breakdown voltage is increased. Therefore, the reliability of the gate dielectric layer is improved. Furthermore, through the arrangement of the first electrode 220F1, the doping concentration of the epitaxial layer 200 can be further increased in order to reduce the on-resistance (Rₒₙₛₚ) of the semiconductor device 500.

In the embodiment shown in FIG. 1, two split gate structures 230AG are disposed in the epitaxial layer 200 of the first region 400 and are located above the lower a portion of the first electrode 220F1. The two split gate structures 230AG are separated from each other along the direction 300 by the epitaxial layer 200. Furthermore, the region of the epitaxial layer 200 between the two split gate structures 230AG may serve as a mesa region 400M of the semiconductor device 500. As shown in FIG. 1, the split gate structure 230AG extends in the direction 320. In some embodiments, the split gate structure 230AG includes the gate dielectric layer 241 and gate electrodes 230AG1, 230AG2 separated from each other along the direction 300. In some embodiments, the split gate structure 230AG may further reduce the whole gate-to-drain capacitance (C_{gd}) and feedback capacitance (Cᵣₛₛ=C_{gd}) to improve the whole power conversion efficiency of the semiconductor device 500.

As shown in FIG. 1, the gate dielectric layer 241 is disposed in the epitaxial layer 200 in the first region 400. The gate dielectric layer 241 may extend from a position close to the top surface 200T of the epitaxial layer 200 into the epitaxial layer 200 along the direction 320. The top portion 220F1-1 of the first electrode 220F1 is exposed from the gate dielectric layer 241 of the split gate structure 230AG. More specifically, the top portion 220F1-1 of the first electrode 220F1 may protrude from a top surface 241T of the gate dielectric layer 241 along the direction 320. In some embodiments, the gate dielectric layer 241 may be a composite structure. For example, the gate dielectric layer 241 may have a first portion 224AR-1 and a second portion 240AR. The first portion 224AR-1 may be located between the gate electrode 230AG1 (or the gate electrode 230AG2) and the first electrode 220F1. The second portion 240AR may be located between a top surface 230AGIT of the gate electrode 230AG1 (or a top surface 230AG2T of the gate electrode 230AG2) and the top surface 241T of the gate dielectric layer 241. In some embodiments, the first portion 224AR-1 has a thickness T1 in the direction 300 and the second portion 240AR has a thickness T2 in the direction 320. In some embodiments, the thickness T2 of the second portion 240AR is greater than the thickness T1 of the first portion 224AR-1. Moreover, a ratio of the thickness T2 to the thickness T1 (i.e., T2/T1) may be between 2 and 3. If the ratio of the thickness T2 to the thickness T1 is less than 2, the thickness of the second portion 240AR may be too thin to provide good electrical isolation between the gate electrodes 230AG1, 230AG2 and the source contact 250S subsequently formed on the gate electrodes 230AG1, 230AG2. If the ratio of the thickness T2 to the thickness T1 is greater than 3, the height at which the top portion 220F1-1 of the first electrode 220F1 protrudes from the gate dielectric layer 241 is too small to facilitate the electrical connection between the first electrode 220F1 and the source contact 250S subsequently formed on the first electrode 220F1.

In some embodiments, the first portion 224AR-1 and the second portion 240AR of the gate dielectric layer 241 may include silicon oxide, silicon nitride, silicon oxynitride, tetraethoxysilane (TEOS) oxide, phosphosilicate glass (PSG), borosilicate glass (BSG), borophosphosilicate glass (BPSG), undoped silicate glass (USG), fluorinated silicate glass (FSG), organosilicate glass (OSG), low dielectric constant dielectric materials, and/or other suitable dielectric materials, or a combination thereof. In this embodiment, the first portion 224AR-1 and the second portion 240AR of the gate dielectric layer 241 may include silicon oxide. In some embodiments, the shielding dielectric layers 216AR, 216BR, 216CR and the gate dielectric layer 241 may be made of the same or different materials according to actual requirements of products. In some embodiments, the first portion 224AR-1 of the gate dielectric layer 241 may be formed by an oxidation process. In some embodiments, the oxidation process may include thermal oxidation or another suitable process. In some embodiments, the second portion 240AR of the gate dielectric layer 241 may be formed using a conformably deposition process, an oxidation process, or another suitable process. In some embodiments, the oxidation process may be thermal oxidation or another suitable process. In some embodiments, the deposition process may be a physical vapor deposition (PVD) process, a chemical vapor deposition (CVD) process, a plasma-enhanced chemical vapor deposition (PECVD) process, another suitable process, or a combination thereof.

The gate electrodes 230AG1 and 230AG2 are located on the opposite sidewalls 220F1S of the first electrode 220F1 and extend in the direction 320. The top surfaces 230AGIT and 230AG2T of the gate electrodes 230AG1 and 230AG2 may be lower than the top surface 200T of the epitaxial layer 200 and the top portion 220F1-1 of the first electrode 220F1. Furthermore, the gate dielectric layer 241 may surround the gate electrodes 230AG1 and 230AG2. In addition, the first electrode 220F1 may extend from below the gate electrodes 230AG1 and 230AG2 to above the gate electrodes 230AG1 and 230AG2 along the direction 320. Furthermore, the first electrode 220F1 may be inserted between the gate electrodes 230AG1 and 230AG2 in the direction 300. The opposite sidewalls 220F1S of the first electrode 220F1 close to the gate electrodes 230AG1, 230AG2 are separated from the gate electrodes 230AG1, 230AG2 by the first portion 224AR-1 of the gate dielectric layer 241.

In some embodiments, the gate electrodes 230AG1 and 230AG2 may be single-layer structures or multi-layer structures and formed of amorphous silicon, polycrystalline silicon, one or more kinds of metals, metal nitride, metal silicide, conductive metal oxide, or a combination thereof. In some embodiments, the metal may include, but are not limited to, tungsten (W), titanium (Ti), tantalum (Ta) or platinum (Pt). In some embodiments, the metal nitrides may include, but are not limited to, titanium nitride (TiN) or tantalum nitride (TaN). In some embodiments, the metal silicide may include, but is not limited to, tungsten silicide (WSiₓ). In some embodiments, the gate electrodes 230AG1, 230AG2 may optionally include a dopant of the second conductivity type. For example, when the silicon carbide substrate 100 is an N-type silicon carbide substrate 100, the gate electrodes 230AG1 and 230AG2 are P-type gate electrodes 230AG1 and 230AG2. Furthermore, the dopant having the second conductivity type may include aluminum (Al), boron (B), boron difluoride (BF₂) or other suitable dopants. In some embodiments, the first electrode 220F1, the second electrode 220F2, and the third electrode 220F3 may include the same or different materials as the gate electrodes 230AG1 and 230AG2.

The semiconductor device 500 may further include a gate dielectric layer 224B and a gate electrode 230BG disposed in the epitaxial layer 200 in the second region 410. The gate dielectric layer 224B may extend from a position close to the top surface 200T of the epitaxial layer 200 into epitaxial layer 200 along the direction 320. Furthermore, the gate dielectric layer 224B may cover the top portion of the second electrode 220F2. The gate electrode 230BG is located on the gate dielectric layer 224B and connected to the split gate structure 230AG. In some embodiments, the gate electrode 230BG extends from opposite sidewall 220F2S of the second electrode 220F2 to cover a top surface 220F2T of the second electrode 220F2 and the top surface 200T of the epitaxial layer 200. The portion of the gate electrode 230BG located on the opposite sidewall 220F2S of the second electrode 220F2 may extend along the direction 320. Furthermore, a portion of the gate electrode 230BG located above the top surface 220F2T of the second electrode 220F2 and the top surface 200T of the epitaxial layer 200 may extend along the direction 300.

The semiconductor device 500 further includes interlayer dielectric layers 240BR and 240CR. The interlayer dielectric layers 240BR and 240CR are disposed on the epitaxial layer 200 in the second region 410 and the third region 420. In addition, the top portion 220F1-1 of the first electrode 220F1, the source region 236, the pick-up doped region 238 and a top surface 230BGT of the gate electrode 230BG are exposed from the interlayer dielectric layers 240BR and 240CR. That is to say, there may be no interlayer dielectric layer located above the top surface 200T of the epitaxial layer 200 in the first region 400. In some embodiments, the interlayer dielectric layers 240BR and 240CR may include silicon oxide, silicon nitride, silicon oxynitride, phosphorus silicate glass (PSG), borophosphosilicate glass (BPSG), or a combination thereof. In some embodiments, the interlayer dielectric layers 240BR and 240CR may be formed using a conformably deposition process, an oxidation process, other suitable formation processes, and a subsequent patterning process. In some embodiments, the oxidation process may be thermal oxidation or other suitable processes. In some embodiments, the deposition process may include a physical vapor deposition (PVD) process, a chemical vapor deposition (CVD) process, a plasma-enhanced chemical vapor deposition (PECVD), another suitable process, or a combination thereof.

The source contact 250S may be disposed on the epitaxial layer 200 in the first region 400. The source contact 250S may cover and may be electrically connected to the top portion 220F1-1 of the first electrode 220F1, the source region 236, and the pick-up doped region 238. The source contact 250S may be electrically connected to the second electrode 220F2 and the third electrode 220F3 through other interconnections (not shown). Furthermore, the gate electrodes 230AG1 and 230AG2 may be separated from the source contact 250S by gate dielectric layer 241. The source contact 250S may have opposite sidewalls 250S1, 250S2 and opposite sidewalls 250S3, 250S4. In some embodiments, the sidewalls 250S1 and 250S3 are adjacent to the first electrode 220F1. In addition, the sidewalls 250S2 and 250S4 are adjacent to the source region 236 and the pick-up doped region 238.

In some embodiments, the source contact 250S has discontinuous lower surfaces 250BS1, 250BS2 and 250BS3. The lower surface 250BS1 is connected to the top portion 220F1-1 of the first electrode 220F1. The lower surface 250BS2 is connected to the gate dielectric layer 241. In addition, the lower surface 250BS3 is connected to the source region 236 and the pick-up doped region 238. In some embodiments, the lower surfaces 250BS1, 250BS2 are not coplanar with each other (i.e., the lower surfaces 250BS1 and 250BS2 are not aligned with each other in the direction 300). In some embodiments, the lower surfaces 250BS2 and 250BS3 are not coplanar with each other (i.e., the lower surfaces 250BS2 and 250BS3 are not aligned with each other in the direction 300). In some embodiments, the lower surfaces 250BS1 and 250BS3 may be coplanar with each other (i.e., the lower surfaces 250BS1 and 250BS3 may be aligned with each other in the direction 300).

In some embodiments, the source contact 250S may include a metal silicide 246S, a contact barrier layer (not shown), and a contact conductive layer 248S. As shown in FIG. 1, the lower surfaces 250BS1 and 250BS3 of the source contact 250S may be formed of the metal silicide 246S, but the lower surface 250BS2 of the source contact 250S is not formed of the metal silicide 246S. Therefore, the metal silicide 246S may be a discontinuous layer formed only on portions of the lower surface of source contact 250S. The metal silicide 246S may cover the top portion 220F1-1 of the first electrode 220F1, the source region 236, and the pick-up doped region 238 exposed from the interlayer dielectric layer 240BR. The contact barrier layer and the contact conductive layer 248S formed thereon may cover the metal silicide 246S and the gate dielectric layer 241.

In some embodiments, the metal silicide 246S includes, for example, tungsten silicide, titanium silicide, cobalt silicide, nickel silicide, platinum silicide, erbium silicide, another suitable metal silicide, or a combination thereof. In some embodiments, a metal layer may be entirely deposited by a deposition processes including chemical vapor deposition (CVD) (e.g., low pressure vapor deposition (LPCVD), plasma enhanced chemical vapor deposition (PECVD)), physical vapor deposition (PVD) (e.g., resistive thermal evaporation, electron beam evaporation or sputtering), electroplating, atomic layer deposition (ALD), another suitable process, or a combination thereof. Then, an annealing process is performed, so that the semiconductor material of the top portion 220F1-1 of the first electrode 220F1, the source region 236 and the pick-up doped region 238 in the first region 400 and not covered by the gate dielectric layer 241 may react with the metal layer to form the metal silicide 246S having a discontinuous distribution. Next, the unreacted metal layer is removed.

In some embodiments, the contact barrier layer may be used to prevent subsequently formed contact conductive layer 248S from diffusing into gate electrodes 230AG1 and 230AG2. The contact barrier layer may be formed of a material including titanium (Ti), titanium nitride (TiN), tantalum (Ta), tantalum nitride (TaN), cobalt (Co), other suitable barrier materials, or a combination thereof. In some embodiments, the contact barrier layer may be formed using a chemical vapor deposition (CVD) process, an atomic layer deposition (ALD) process, a physical vapor deposition (PVD) process, another suitable process, or a combination thereof.

In some embodiments, the contact conductive layer 248S of the source contact 250S may be a single-layer or a multi-layer structure. The contact conductive layer 248S may be formed of a material including tungsten (W), aluminum (Al), copper (Cu), titanium (Ti), tantalum (Ta), titanium nitride (TiN), tantalum nitride (TaN), nickel silicide (NiSi), cobalt silicide (CoSi), other suitable metals, or a combination thereof. In some embodiments, the contact conductive layer 248S may be formed using a chemical vapor deposition (CVD) process, an atomic layer deposition (ALD) process, a physical vapor deposition (PVD) process, another suitable process, or a combination thereof.

The semiconductor device 500 may further include a gate contact 250G. The gate contact 250G is disposed on the epitaxial layer 200 in the second region 410. The gate contact 250G passes from above the interlayer dielectric layer 240BR through the interlayer dielectric layer 240BR along the direction 320 to cover and electrically connect the gate electrode 230BG. Similar to the source contact 250S, the gate contact 250G may include a metal silicide 246G, a contact barrier layer (not shown), and a contact conductive layer 248G. The metal silicide 246G may cover the gate electrode 230BG. The contact barrier layer and the contact conductive layer 248G formed on the contact barrier layer may cover the metal silicide 246G and the interlayer dielectric layer 240BR. In some embodiments, the metal silicides 246S and 246G may include the same or similar materials and processes, and may be formed simultaneously. The contact conductive layers 248S and 248G may include the same or similar materials and processes, and may be formed simultaneously.

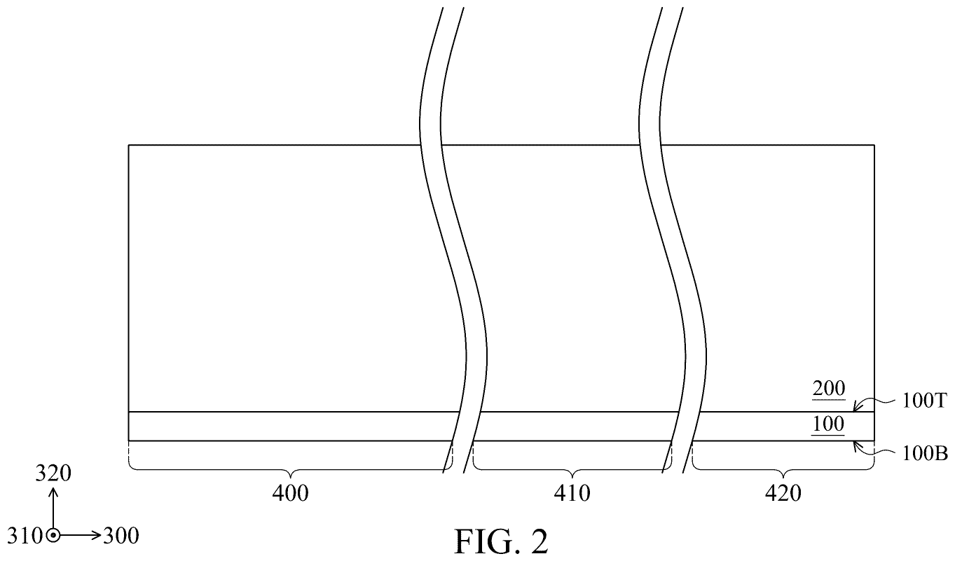

The method for forming the semiconductor device 500 in accordance with some embodiments of the disclosure will be described with reference to FIGS. 2 to 19. FIGS. 2 to 19 are schematic cross-sectional views of intermediate stages of forming the semiconductor device 500 of FIG. 1 in accordance with some embodiments of the disclosure, in which the reference numbers the same or similar to those in FIG. 1 denote the same or similar elements.

As shown in FIG. 2, the silicon carbide substrate 100 having the first conductivity type, for example, an N-type heavily doped (N+) silicon carbide substrate 100, is provided.

Next, an epitaxial growth process is performed to grow the epitaxial layer 200 of the first conductivity type, such as an N-type lightly doped (N−) silicon carbide epitaxial layer 200, on the top surface 100T of the silicon carbide substrate 100. In some embodiments, the epitaxial process includes metal organic chemical vapor deposition (MOCVD), plasma-enhanced chemical vapor deposition (PECVD), molecular beam epitaxy (MBE), hydride vapor phase epitaxy (HVPE), liquid phase epitaxy (LPE), chloride vapor phase epitaxy (Cl-VPE), other suitable epitaxial growth processes or a combination thereof.

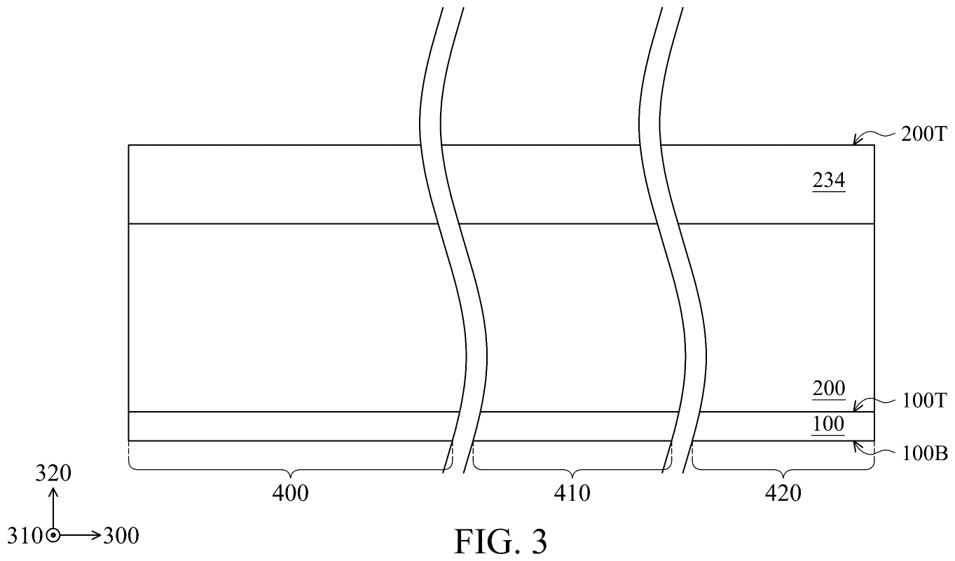

Next, as shown in FIG. 3, an ion implantation process may be performed to entirely form the well region 234 having the second conductivity type, such as a P-type well region 234, in the epitaxial layer 200. The well region 234 may extend from the top surface 200T of the epitaxial layer 200 into a portion of the epitaxial layer 200.

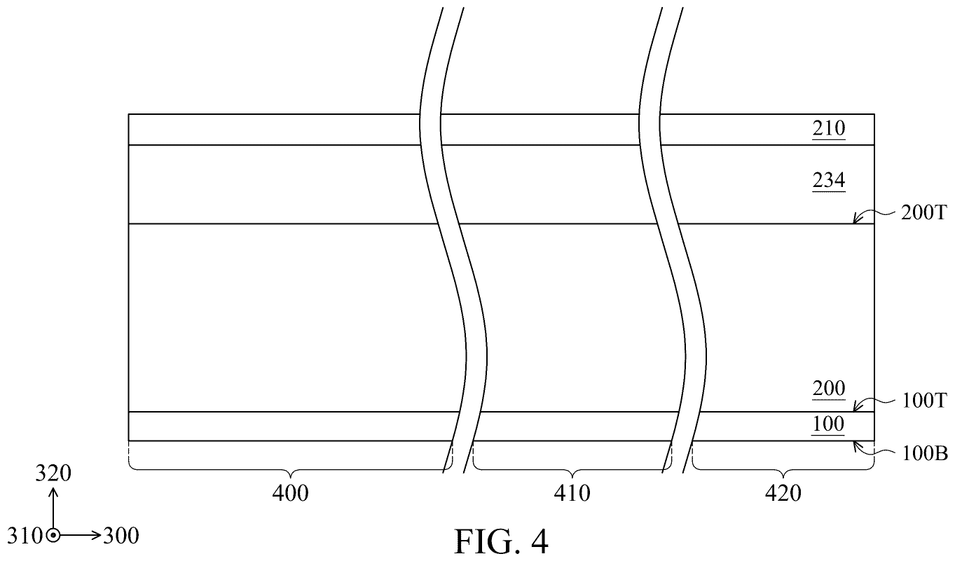

Next, as shown in FIG. 4, a deposition process may be performed to form a mask layer 210 on the epitaxial layer 200. In some embodiments, the mask layer 210 may be a single-layer structure or a multi-layer structure. In some embodiments, the mask layer 210 may include an insulating material such as silicon oxide.

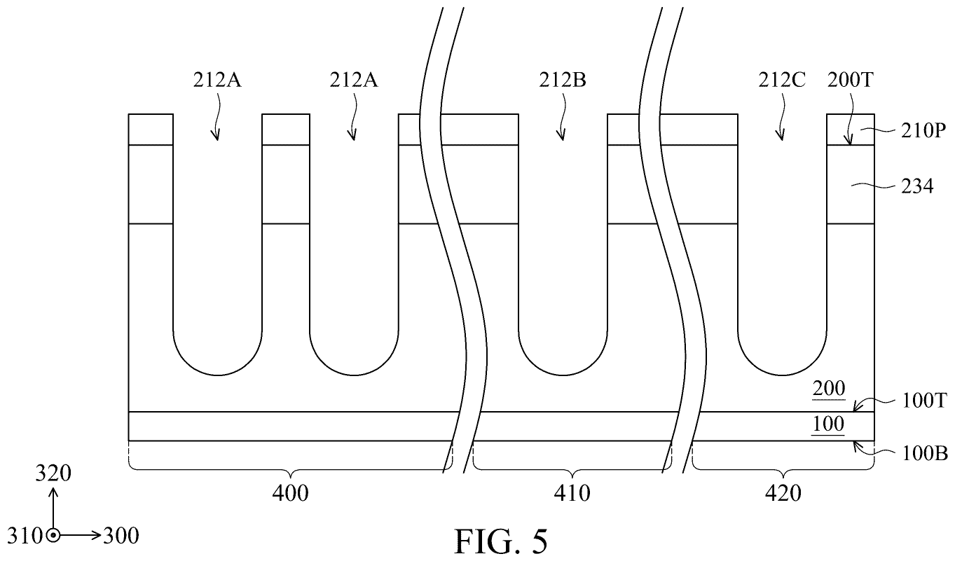

Next, as shown in FIG. 5, a photolithography process and a subsequent patterning process are performed to remove a portion of the mask layer 210, thereby forming a mask pattern 210P on the top surface 200T of the epitaxial layer 200 to define the formation locations of trenches. Next, an etching process is performed on the epitaxial layer 200 using the mask pattern 210P as an etching mask. The etching process removes the epitaxial layer 200 not covered by the mask pattern 210P to form trenches 212A, 212B, 212C in the epitaxial layer 200 in the first region 400, the second region 410, and the third region 420 respectively along the direction 320. In the embodiment shown in FIG. 5, the etching process may form two trenches 212A in the epitaxial layer 200 in the first region 400, form one trench 212B in the epitaxial layer 200 in the second region 410 and form one trench 212C in the epitaxial layer 200 in the third region 420. The two adjacent trenches 212A are spaced apart from each other along the direction 300 and define the mesa region 400M of the epitaxial layer 200. In some embodiments, the etching process includes dry etching. Dry etching may include plasma etching, plasma-free gas etching, sputter etching, ion milling, reactive ion etching (RIE), neutral beam etch (NBE), inductive coupled plasma etch (inductive coupled plasma etch) or another suitable process.

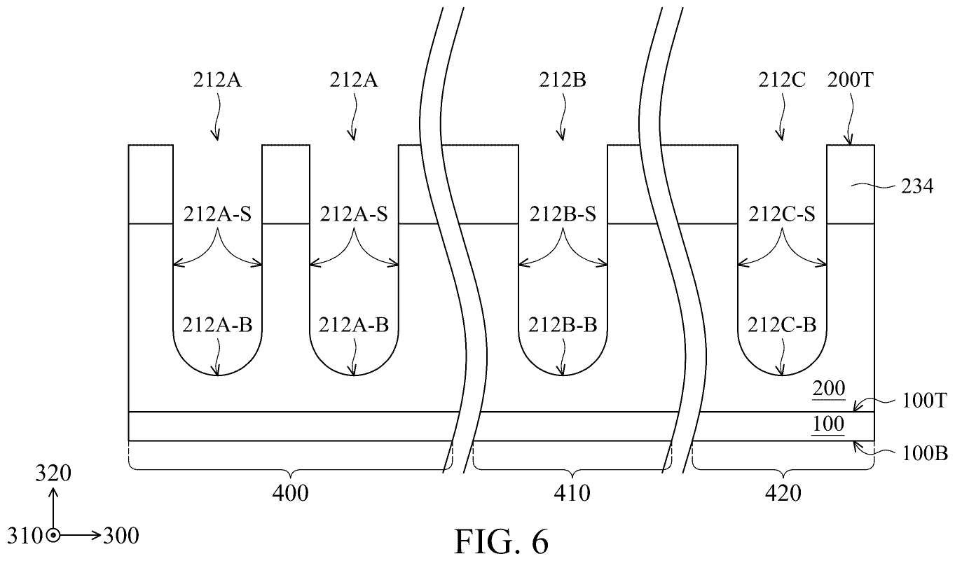

Next, as shown in FIG. 6, a selective etching process may be performed to remove the mask pattern 210P. Next, an oxidation process and a subsequent etching process may be performed to form a sacrificial (SAC) oxide layer (not shown) on sidewalls 212A-S, 212B-S, 212C-S and bottom surfaces 212A-B, 212B-B, 212C-B of the trenches 212A, 212B, and 212C. Another etching process is then performed to remove the sacrificial oxide layer, so that the sidewalls 212A-S, 212B-S, 212C-S and the bottom surfaces 212A-B, 212B-B, 212C-B of the trenches 212A, 212B, and 212C are exposed again. The oxidation process and etching process shown in FIG. 6 may remove the surface damage caused by the etching process (FIG. 5) that forms trenches 212A, 212B, and 212C.

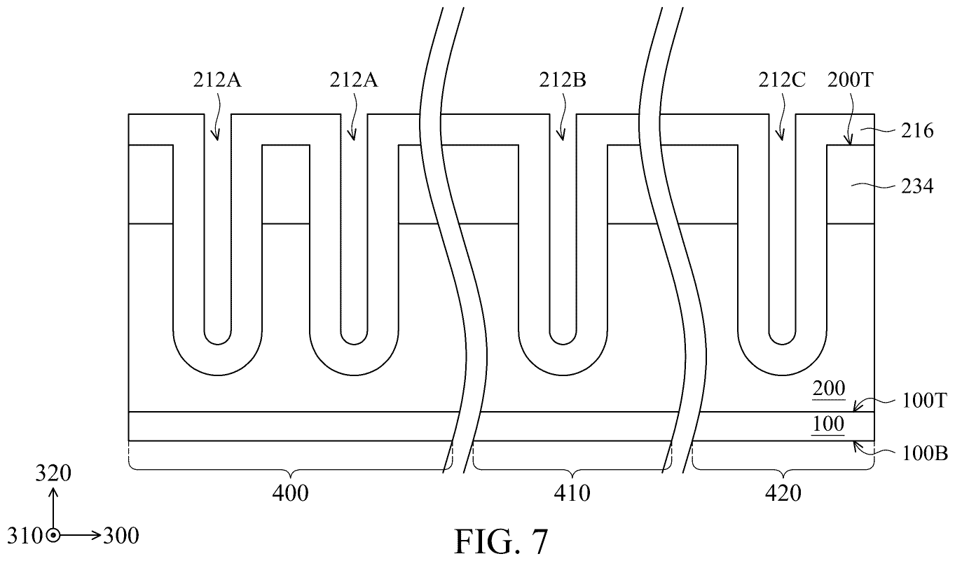

Next, as shown in FIG. 7, an oxidation process and a subsequent deposition process may be performed to entirely form a shielding dielectric layer 216. The shielding dielectric layer 216 may cover the top surface 200T of the epitaxial layer 200 and extend into the trenches 212A, 212B and 212C. In addition, the shielding dielectric layer 216 may conformally cover the sidewalls 212A-S, 212B-S, 212C-S and the bottom surfaces 212A-B, 212B-B, 212C-B of the trenches 212A, 212B and 212C (FIG. 6).

In some embodiments, the dielectric layer 216 may be optionally subjected to a thermal process to increase the density of the shielding dielectric layer 216 and improve the interface properties between the shielding dielectric layer 216 and the epitaxial layer 200. In some embodiments, the thermal process may be a rapid thermal annealing (RTA) process.

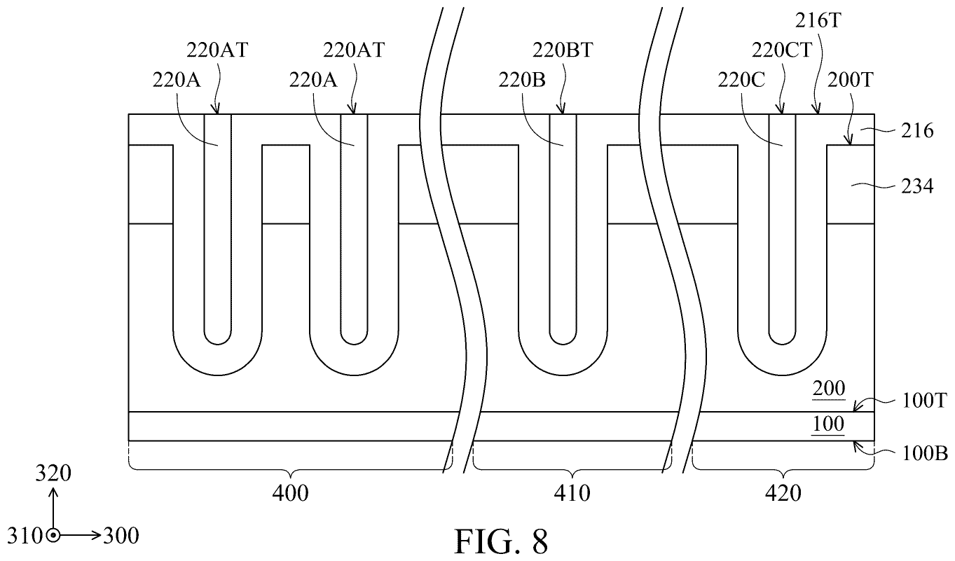

Next, as shown in FIG. 8, a deposition process and a subsequent planarization process may be performed to form conductive materials 220A, 220B, and 220C in the trenches 212A, 212B, and 212C (FIG. 7) respectively. In some embodiments, the conductive materials 220A, 220B, and 220C are formed simultaneously. A top surface 220AT of the conductive material 220A, a top surface 220BT of the conductive material 220B, and a top surface 220CT of the conductive material 220C are all higher than the top surface 200T of the epitaxial layer 200 and are aligned with each other. For example, the top surface 220AT of the conductive material 220A, the top surface 220BT of the conductive material 220B, and the top surface 220CT of the conductive material 220C are all aligned with the top surface 216T of the shielding dielectric layer 216. Furthermore, the conductive materials 220A, 220B, and 220C may include the same material. In some embodiments, the conductive materials 220A, 220B, and 220C may be formed of amorphous silicon, polycrystalline silicon, one or more kinds of metals, metal nitrides, metal silicides, conductive metal oxides, or a combination thereof. In some embodiments, the metals may include, but are not limited to, tungsten (W), titanium (Ti), tantalum (Ta), and platinum (Pt). In some embodiments, the metal nitrides may include, but are not limited to, titanium nitride (TiN) and tantalum nitride (TaN). In some embodiments, the metal silicides may include, but is not limited to, tungsten silicide (WSiₓ). In some embodiments, the deposition process may include metal organic chemical vapor deposition (MOCVD), sputtering, resistance heating evaporation, electron beam evaporation, or other suitable deposition processes. In some embodiments, the planarization process includes a chemical mechanical polishing (CMP) process.

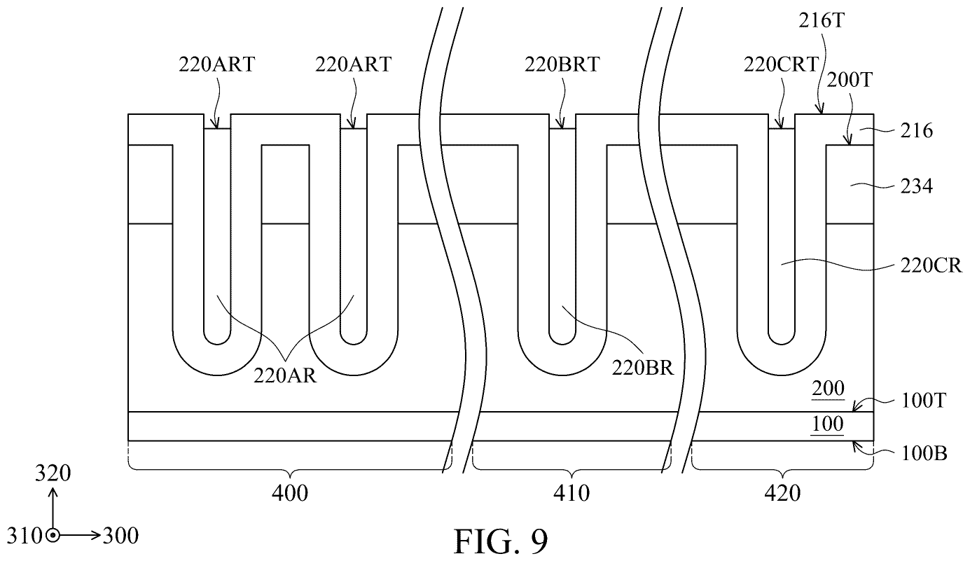

Nest, as shown in FIG. 9, an etch-back process may be performed to remove a portion of the conductive materials 220A, 220B, 220C from the top surfaces 220AT, 220BT, 220CT of the conductive materials 220A, 220B, 220C. After performing the etching back process, the remaining conductive materials 220A, 220B, and 220C are denoted as conductive materials 220AR, 220BR, and 220CR. Top surfaces 220ART, 220BRT, 220CRT of the conductive materials 220AR, 220BR, and 220CR may be located above the top surface 200T of the epitaxial layer 200. For example, the top surfaces 220ART, 220BRT, and 220CRT of the conductive materials 220AR, 220BR, and 220CR may be higher than the top surface 200T of the epitaxial layer 200 and lower than the top surface 216T of the shielding dielectric layer 216. In some embodiments, the etch-back process may be a selective etching process, such as dry etching.

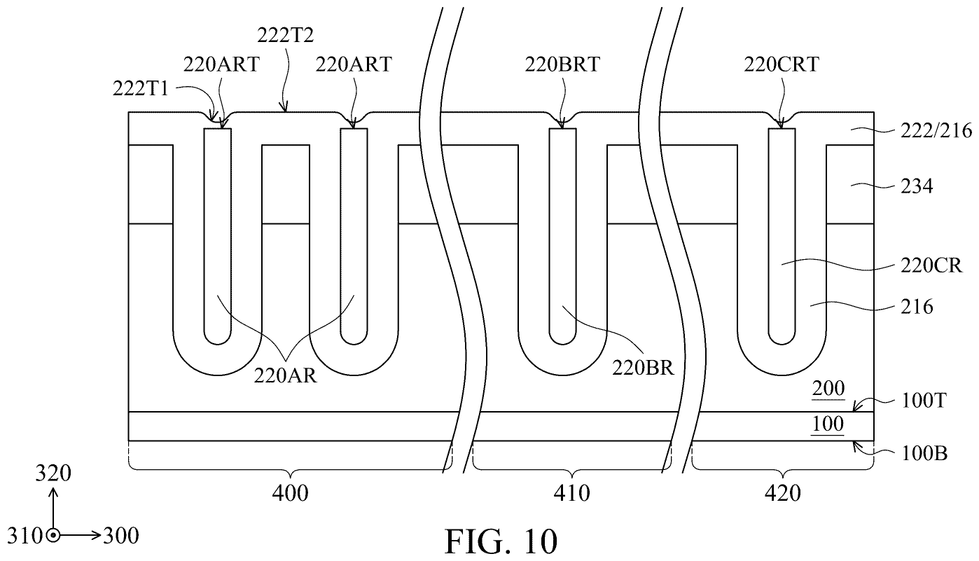

Next, as shown in FIG. 10, a deposition process may be performed to entirely form an oxide layer 222. The oxide layer 222 may cover the shielding dielectric layer 216 and the conductive materials 220A, 220B, 220C. When the oxide layer 222 and the shielding dielectric layer 216 both include silicon oxide, there is no obvious interface between the oxide layer 222 and the shielding dielectric layer 216. In some embodiments, the oxide layer 222 includes tetraethoxysilane (TEOS) oxide formed using low pressure chemical vapor deposition (LPCVD). Since the top surfaces 220ART, 220BRT, and 220CRT of the conductive materials 220AR, 220BR, and 220CR are lower than the top surface 216T of the shielding dielectric layer 216, an upper surface 222T1 of a portion of the oxide layer 222 directly above the conductive materials 220AR, 220BR, 220CR will be lower than an upper surface 222T2 of another portion of the oxide layer 222 directly above the shielding dielectric layer 216.

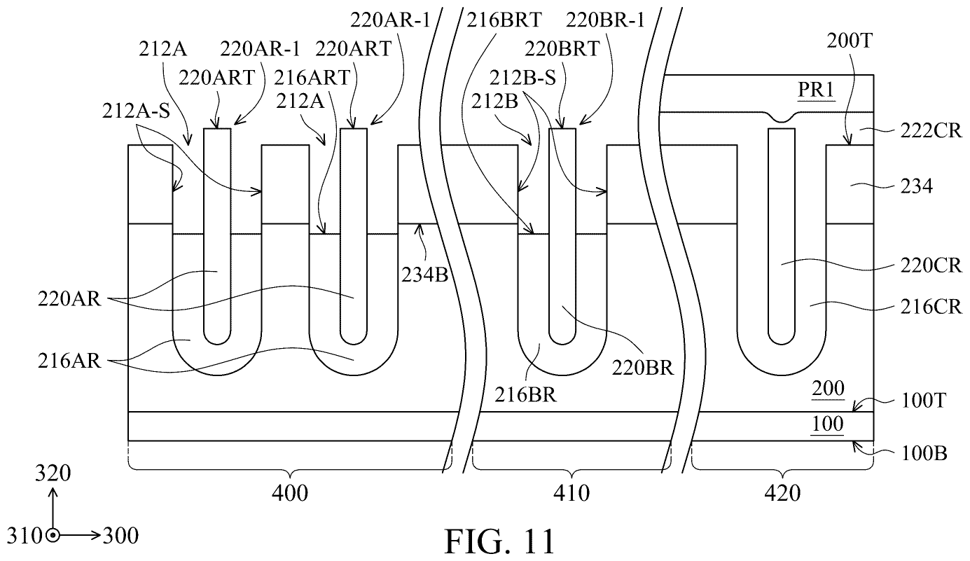

Next, as shown in FIG. 11, a photolithography process may be performed to form a photoresist pattern PR1 above the epitaxial layer 200 in the third region 420. The photoresist pattern PR1 may cover the conductive material 220CR and a portion of the shielding dielectric layer 216 and oxide layer 222 in the third region 420. In addition, a portion of the oxide layer 222 in the first region 400 and the second region 410 (FIG. 10) is exposed from the photoresist pattern PR1. Next, a selective etching process may be performed to remove the oxide layer 222 and a portion of the shielding dielectric layer 216 from the top surface 200T of the epitaxial layer 200 and the upper portions of the trenches 212A and 212B close to the top surface 200T of the epitaxial layer 200 (FIG. 10) until the upper portions 220AR-1 and 220BR-1 of the conductive materials 220AR and 220BR are exposed. After performing the selective etching process, the shielding dielectric layer 216 remaining in the trenches 212A and 212B of the first region 400 and the second region 410 is denoted as the shielding dielectric layer 216AR and 216BR. The shielding dielectric layers 216AR and 216BR may surround the lower portions of the conductive materials 220AR and 220BR, and expose the sidewalls 212A-S and 212B-S of the upper portions of the trenches 212A and 212B. The top surfaces 216ART and 216BRT of the shielding dielectric layers 216AR and 216BR may be located below the bottom surface 234B of the well region 234. In some embodiments, the selective etching process includes wet etching. After forming the shielding dielectric layers 216AR and 216BR, the photoresist pattern PR1 is removed.

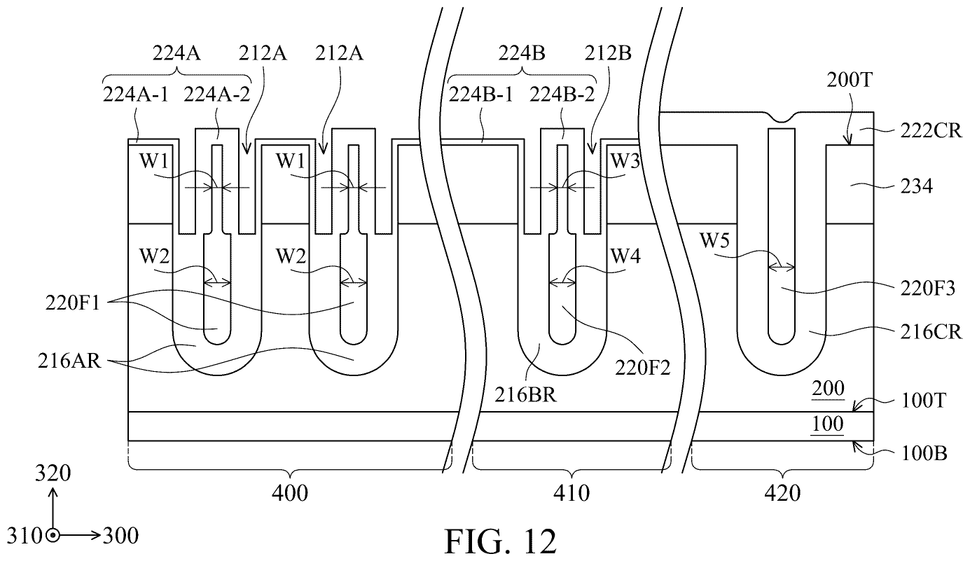

Next, as shown in FIG. 12, an oxidation process may be performed to form a gate dielectric layer 224A in the trench 212A and a gate dielectric layer 224B in the trench 212B simultaneously. The oxidation process includes oxidizing the sidewalls 212A-S of the upper portion of the trench 212A and the surface portion of the upper portion 220AR-1 of the conductive material 220AR (FIG. 11) to form the gate dielectric layer 224A and the first electrode 220F1 in the trench 212A. The oxidation process also includes oxidizing the sidewalls 212B-S of the upper portion of the trench 212B and the surface portion of the upper portion 220BR-1 of the conductive material 220BR (FIG. 11) to form the gate dielectric layer 224B and the second electrode 220F2 in the second trench 212B. The shielding dielectric layers 216AR and 216BR may surround the lower portions of the conductive materials 220AR and 220BR, so the lower portions of the conductive materials 220AR and 220BR will not become oxidized. When the gate dielectric layers 224A, 224B and the shielding dielectric layers 216AR, 216BR all include silicon oxide, there is no obvious interface between the gate dielectric layer 224A and the shielding dielectric layer 216AR (or between the gate dielectric layer 224B and the shielding dielectric layer 216BR). Furthermore, the gate dielectric layers 224A and 224B may extend to cover the top surface 200T of the epitaxial layer 200 in the first region 400 and the second region 410. The oxidation process may also include forming an oxide layer (not shown) on the oxide layer 222CR in the third region 420.

In some embodiments, the gate dielectric layer 224A does not fill up the trench 212A. Furthermore, the gate dielectric layer 224A includes a gate dielectric layer 224A-1 conformally formed on the sidewalls 212A-S (FIG. 11) of the upper portion of the trench 212A, and a gate dielectric layer 224A-2 surrounding the upper portion of the first electrode 220F1. Similarly, the gate dielectric layer 224B does not fill up the trench 212B. Furthermore, the gate dielectric layer 224B includes a gate dielectric layer 224B-1 conformally formed on the sidewalls 212B-S (FIG. 11) of the upper portion of the trench 212B, and a gate dielectric layer 224B-2 surrounding the upper portion of the second electrode 220F2. In some embodiments, the thicknesses of the gate dielectric layers 224A-1 and 224A-2 are less than the thickness of the shielding dielectric layers 216AR and 216BR. Compared to the gate dielectric layers 224A-1 and 224B-1, which are formed by oxidizing the epitaxial layer 200 formed of silicon carbide, for example, the gate dielectric layers 224A-2 and 224B-2 are formed by oxidizing the conductive materials 220AR and 220BR (FIG. 11) formed of polycrystalline silicon, for example. Therefore, the gate dielectric layers 224A-2 and 224B-2 may have a thicker thickness.

After performing the oxidation process, the unoxidized conductive material 220AR in the trench 212A may form the first electrode 220F1, the unoxidized conductive material 220BR in the trench 212B may form the second electrode 220F2, and the unoxidized conductive material 220CR in the trench 212C may form the third electrode 220F3. In some embodiments, the first electrode 220F1, the second electrode 220F2, and the third electrode 220F3 extend along the direction 320. In the direction 300, since the gate dielectric layers 224A-2 and 224B-2 have a thickness thicker than the gate dielectric layers 224A-1 and 224B-1, the width W1 of the upper portion of the first electrode 220F1 (i.e., the upper portion 220AR-1 of the unoxidized conductive material 220) may be smaller than the width W2 of the lower portion of the first electrode 220F1 (i.e., the portion surrounded by the shielding dielectric layer 216AR). Similarly, in the direction 300, the width W3 of the upper portion of the second electrode 220F2 (i.e., the upper portion 220BR-1 of the unoxidized conductive material 220B) may be smaller than the width W4 of the lower portion of the second electrode 220F2 (i.e., the portion surrounded by the shielding dielectric layer 216BR). In some embodiments, the width W1 may be equal to the width W3. In addition, the width W2 may be equal to the width W4. Furthermore, in the direction 300, the third electrode 220F3 has a uniform width W5. In some embodiments, the width W5 may be equal to the widths W1 and W3.

In some embodiments, the above-mentioned oxidation process may be thermal oxidation or another suitable process. In some embodiments, the gate dielectric layers 224A, 224B are formed by an oxidation process and a subsequent deposition process. In some embodiments, the deposition process may be low pressure chemical vapor deposition (LPCVD) or another suitable process.

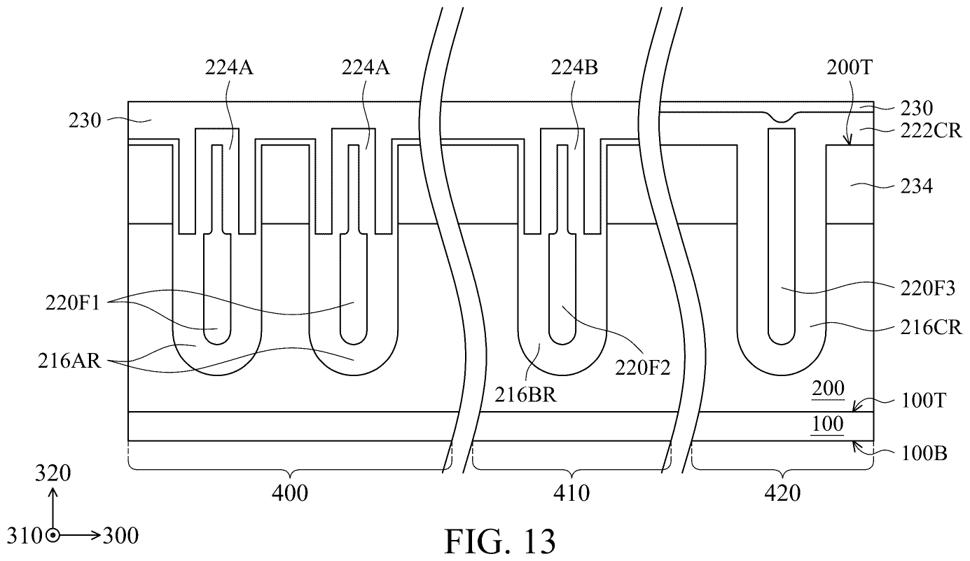

Next, as shown in FIG. 13, a deposition process and a subsequent planarization process may be performed to entirely form an electrode material 230 on the epitaxial layer 200. The electrode material 230 may cover the gate dielectric layers 224A and 224B in the first region 400 and the second region 410 and the oxide layer 222CR in the third region 420. Furthermore, electrode material 230 may fill the trenches 212A and 212B (FIG. 12). In some embodiments, the electrode material 230, the first electrode 220F1, the second electrode 220F2, and the third electrode 220F3 may include the same material, such as polysilicon. In some embodiments, the deposition process may include metal organic chemical vapor deposition (MOCVD), sputtering, resistive thermal evaporation, electron beam evaporation, or another suitable deposition process. In some embodiments, the planarization process includes a chemical mechanical polishing (CMP) process.

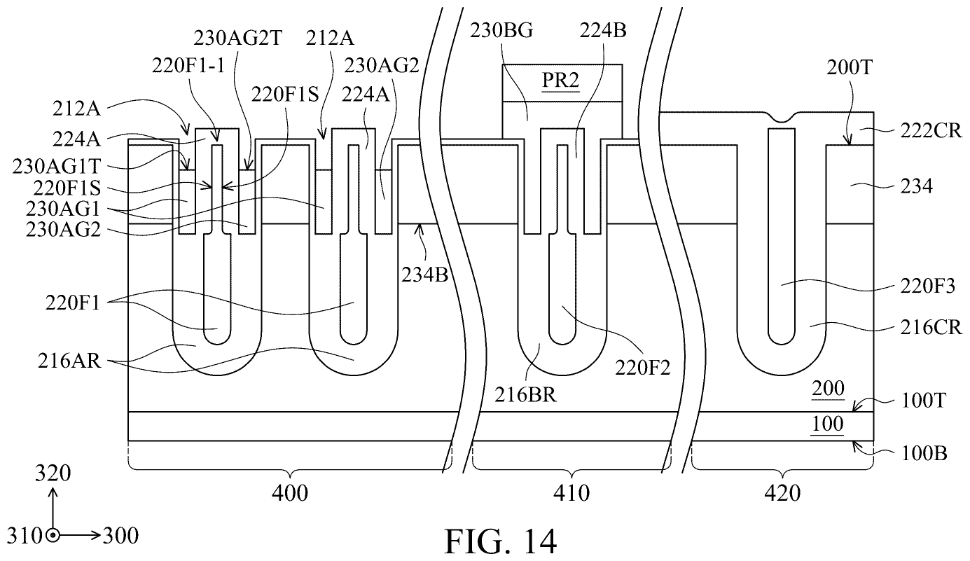

Next, as shown in FIG. 14, a patterning process may be performed to remove a portion of the electrode material 230 above the epitaxial layer 200 in the first region 400 and the third region 420 (FIG. 13). The patterning process may include a photolithography process and a subsequent selective etching process. The photolithography process may form a photoresist pattern PR2 above the epitaxial layer 200 in the second region 410. The photoresist pattern PR2 may cover the electrode material 230 in the second region 410 and expose the electrode material 230 in the first region 400 and the third region 420. Next, a selective etching process may be performed to remove the electrode material 230 located on the top surface 200T of the epitaxial layer 200 in the first region 400 and the upper portion of the trench 212A close to the top surface 200T of the epitaxial layer 200 to form the gate electrodes 230AG1 and 230AG2 on the opposite sidewalls 220F1S of the first electrode 220F1 in the trench 212A. The gate electrodes 230AG1 and 230AG2 are separated from each other in the direction 300 and extend along the direction 320. The gate electrodes 230AG1 and 230AG2 may extend below a bottom surface 234B of the well region 234 along the direction 320. In some embodiments, the gate electrodes 230AG1 and 230AG2 do not fill up the trench 212A. In some embodiments, the top portion 220F1-1 of the first electrode 220F1 is located above the top surface 230AG2T of the gate electrode 230AG1 and the top surface 230AG2T of the gate electrode 230AG2.

As shown in FIG. 14, the selective etching process may also remove the electrode material 230 on the oxide layer 222CR in the third region 420. After performing the selective etching process, the gate electrode 230BG may be formed above the epitaxial layer 200 in the second region 410 and in the trench 212B (FIG. 12). In some embodiments, the gate electrode 230BG may fill up the remaining space of the trench 212B and extend to cover the second electrode 20F2 and the epitaxial layer 200 outside the trench 212B. Since the electrode material 230 is formed of a material that is different from the gate dielectric layer 224A and the oxide layer 222CR, the gate dielectric layers 224A, 224B and the oxide layer 222CR will not be removed by the above selective etching process. In some embodiments, the selective etching process includes dry etching. After forming the gate electrodes 230AG1, 230AG2, and 230BG, the photoresist pattern PR2 is removed.

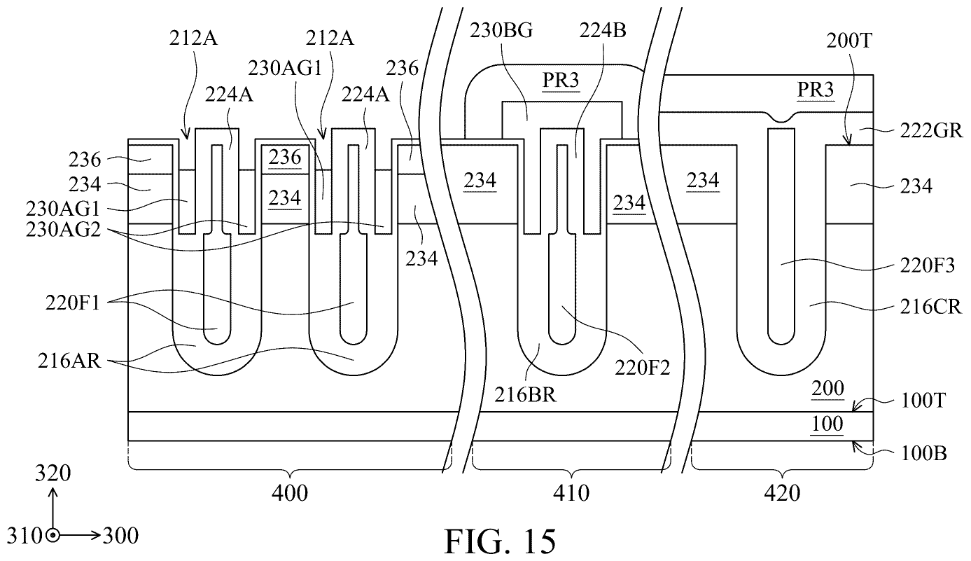

The formations of the source region 236 and the pick-up doped region 238 will be described with reference to FIGS. 15 and 16 respectively. Furthermore, the formation positions of the source region 236 and the pick-up doped region 238 in the first region 400 will be described with reference to FIG. 20. In order to illustrate the arrangement of the source region 236 and the pick-up doped region 238, the gate dielectric layer 224A-1 covering the top surface 200T of the epitaxial layer 200 is not shown in FIG. 20. FIGS. 15 and 16 illustrate cross-sectional views of the intermediate structure of the semiconductor device 500 at different positions in the direction 310 in accordance with some embodiments of the disclosure. FIG. 20 is a schematic top view of an intermediate stage of forming the semiconductor device 500 of FIG. 1 in accordance with some embodiments of the disclosure, showing the arrangement of the source region 236 and the pick-up doped region 238 above the well region 234. The first region 400 shown in FIGS. 15 and 16 may respectively correspond to the cross-sectional positions taken along the line A-A′ and the line B-B′ in FIG. 20 to illustrate the formation of the source regions 236 and the pick-up doped regions 238 located in the epitaxial layer 200 in the first region 400 and alternately arranged in the direction 310.

As shown in FIG. 15, a photolithography process may be performed to form a photoresist pattern PR3 above the epitaxial layer 200 in the second region 410 and the third region 420, exposing the predetermined formation region of the source region 236 in the first region 400 (corresponding to the formation region of the source region 236 in FIG. 20). Next, an ion implantation process is performed to form a source region 236 of the first conductivity type (for example, an N-type source region 236) on the well region 234 in the first region 400. After forming the source region 236, the photoresist pattern PR3 is removed.

As shown in FIG. 16, another photolithography process may be performed to form a photoresist pattern PR4 above the epitaxial layer 200 in the second region 410 and the third region 420, exposing the predetermined formation region of the pick-up doped region 238 in the first region 400 (corresponding to the formation region of the pick-up doped region 238 in FIG. 20). It is noted that the predetermined formation regions of the source region 236 and the pick-up doped region 238 are respectively located in different regions of the epitaxial layer 200 that are alternately arranged along the direction 310 (FIG. 20). Next, an ion implantation process is performed to form a pick-up doped region 238 of the second conductivity type (for example, a P-type pick-up doped region 238) on the well region 234 in the first region 400. After forming the pick-up doped region 238, the photoresist pattern PR4 is removed.

In some embodiments, each of the source region 236 and the pick-up doped region 238 are disposed in the epitaxial layer 200 between the two adjacent pairs of the gate electrodes 230AG1 and 230AG2 along the direction 300. In the direction 300, there is no other doped region between the opposite sidewalls of each of the source region 236 and the pick-up doped region 238 and the two adjacent gate electrodes 230AG1 and 230AG2 of the two adjacent pairs of the gate electrodes 230AG1 and 230AG2 that are close to each other.

In some embodiments, the process sequences shown in FIGS. 15 and 16 may be interchanged. That is to say, the pick-up doped region 238 may be formed first, and then the source region 236 may be formed.

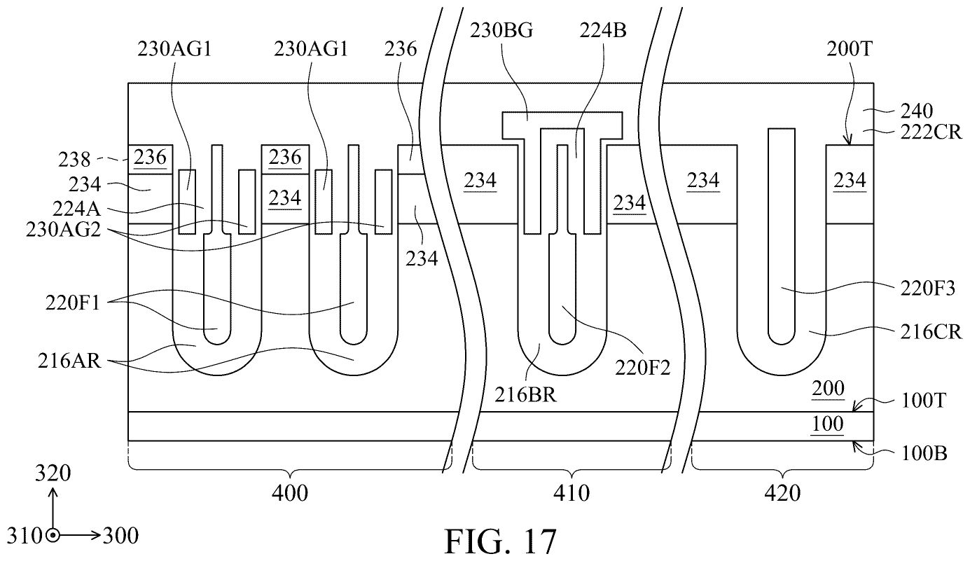

Next, as shown in FIG. 17, a deposition process and a subsequent planarization process may be performed to entirely form an interlayer dielectric layer 240 on the epitaxial layer 200. The interlayer dielectric layer 240 may cover the gate electrodes 230AG1, 230AG2, 230BG, the gate dielectric layers 224A, 224B and the oxide layer 222CR. In addition, the interlayer dielectric layer 240 may fill up the trench 212A (FIG. 16). When the gate dielectric layers 224A and 224B, the oxide layer 222CR and the interlayer dielectric layer 240 all include silicon oxide, there are no obvious interfaces between the interlayer dielectric layer 240 and the gate dielectric layers 224A and 224B and the oxide layer 222CR. In some embodiments, the planarization process includes a chemical mechanical polishing (CMP) process.

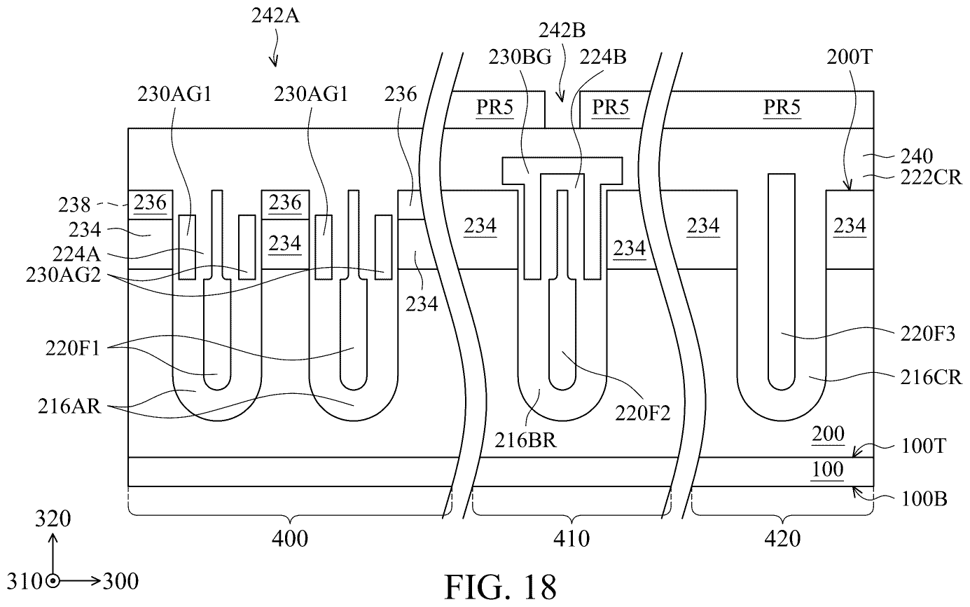

Next, as shown in FIG. 18, a photolithography process may be performed to form a photoresist pattern PR5 on the epitaxial layer 200. The photoresist pattern PR5 has an opening 242A that exposes the entire first region 400, and an opening 242B located directly above the gate electrode 230BG in the second region 410. Moreover, the photoresist pattern PR5 completely covers the epitaxial layer 200 and the interlayer dielectric layer 240 in the third region 420. The opening 242A may have a large enough size to expose the whole first region 400. In addition, the opening 242B only needs to be located directly above the gate electrode 230BG. Therefore, there is no need to use a high-resolution mask such as a deep ultraviolet (DUV) mask (for example, the I-line mask having lower resolution may be used instead). The cost of the lithography process cost will be reduced.

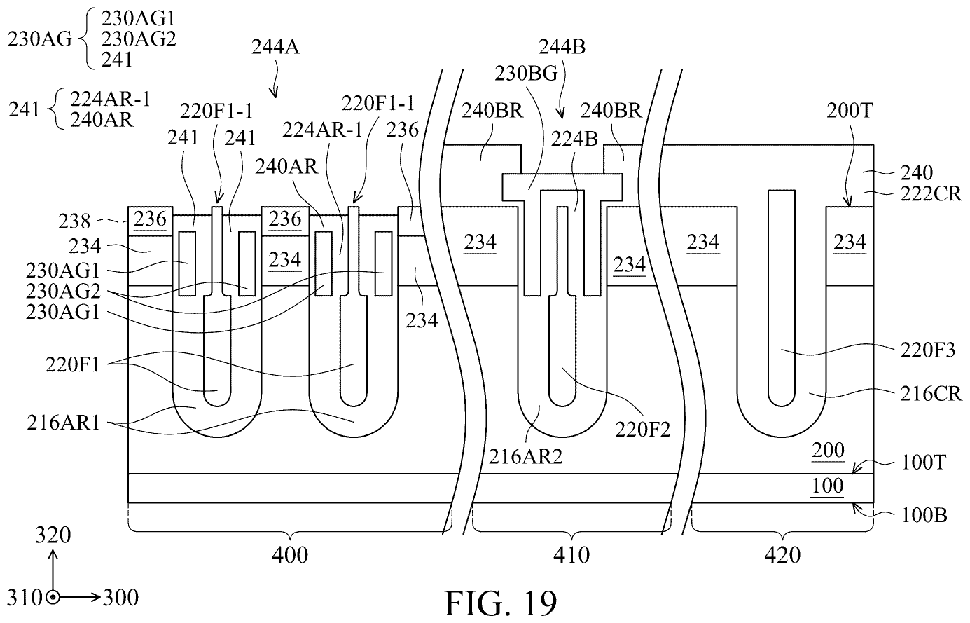

Next, as shown in FIG. 19, an etching process may be performed to remove the interlayer dielectric layer 240 and gate dielectric layer 224A on the top surface 200T of the epitaxial layer 200 in the first region 400 and the upper portion of the first trench 212A exposed from the opening 242A of the photoresist pattern PR5 (FIG. 18), thereby forming an opening (a contact hole) 244A in the interlayer dielectric layer 240 that exposes the entire first region 400. In addition, the top portion 220F1-1 of the first electrode 220F1, the source region 236 and the pick-up doped region 238 are exposed from the opening 244A. The etching process may be also performed to form an opening (a contact hole) 244B in a portion of the interlayer dielectric layer 240 directly above the gate electrode 230BG in the second region 410. In addition, the gate electrode 230BG is exposed from the opening 244B. In some embodiments, the etching process includes dry etching and subsequent wet etching. First, the most portion of the interlayer dielectric layer 240 above the top surface 200T of the epitaxial layer 200 and not covered by the photoresist pattern PR5 may be removed by dry etching. The remaining interlayer dielectric layer 240 may cover the source region 236 and the pick-up doped region 238 to prevent the source region 236 and the pick-up doped region 238 from being damaged during dry etching. Next, a portion of the interlayer dielectric layer 240 may be removed by wet etching until the top portion 220F1-1 of the first electrode 220F1, the source region 236, the pick-up doped region 238 and the gate electrode 230BG are exposed. After performing the etching process, the remaining interlayer dielectric layer 240 and the remaining gate dielectric layer 224A in the first region 400 may collectively form the gate dielectric layer 241. The gate dielectric layer 241, the gate electrodes 230AG1 and 230AG2 may collectively form the split gate structure 230AG. The remaining gate dielectric layer 224A may serve as (denoted as) the first portion 224AR-1 of the gate dielectric layer 241. The remaining interlayer dielectric layer 240 may serve as (denoted as) a second portion 240AR of the gate dielectric layer 241. Moreover, the remaining interlayer dielectric layers 240 in the second region 410 and the third region 420 are respectively denoted as the interlayer dielectric layers 240BR and 240CR. After forming the gate dielectric layer 241 and the interlayer dielectric layers 240BR and 240CR, the photoresist pattern PR5 is removed.

Next, as shown in FIG. 1, a deposition process and a subsequent annealing process and a removal process may be performed to form the metal silicide 246S discontinuously distributed on and self-aligned with the top portion 220F1-1 of the first electrode 220F1, the source region 236 and the pick-up doped region 238 in the opening (the contact hole) 244A in the first region 400, and the metal silicide 246 continuously distributed on and self-aligned with the gate electrode 230BG in the opening (the contact hole) 244B of the second region 410.

Then, as shown in FIG. 1, a deposition process and a subsequent patterning process may be performed to form a contact barrier layer (not shown) and a contact conductive layer 248S on the top portion 220F1-1 of the first electrode 220F1, the source region 236 and the pick-up doped region 238 in the opening (the contact hole) 244A (FIG. 19) in the first region 400. The deposition process and the subsequent patterning process may be also performed to form the contact barrier layer (not shown) and the contact conductive layer 248G on the gate electrode 230BG in the opening (the contact hole) 244B (FIG. 19) of the second region 410. The contact barrier layer maybe conformally deposited on the epitaxial layer 200 and the gate dielectric layer 241 in the opening (contact hole) 244A of the first region 400, and in the opening (contact hole) 244B of the second region 410. The contact conductive layer 248S may fill the opening (the contact hole) 244A, and covers the first electrode 220F1, the source region 236 and the pick-up doped region 238. Furthermore, the contact conductive layer 248G may cover the interlayer dielectric layer 240BR in the second region 410 and fill up the remaining space in the opening (the contact hole) 244B. The interlayer dielectric layer 240CR in the third region 420 is not covered by the contact barrier layer and the contact conductive layer. After the aforementioned processes, the source contact 250S (including the metal silicon 246S, the contact barrier layer (not shown) and the contact conductive layer 248S) is formed on the epitaxial layer 200 in the first region 400. In addition, the gate contact 250G (including the metal silicide 246G, the contact barrier layer (not shown) and the contact conductive layer 248G) is formed on the epitaxial layer 200 in the second region 410 simultaneously.

Subsequent processes may be further performed to form a drain contact (not shown) on the bottom surface 100B of the silicon carbide substrate 100. The drain contact may be electrically connected to the silicon carbide substrate 100. After performing the aforementioned processes, the semiconductor device 500 is formed.

Embodiments provide a semiconductor device and a method for forming the same. The semiconductor device includes a shielded gate trench metal-oxide-semiconductor field-effect transistor (SGT MOSFET) unit formed in a cell region (e.g., the first region 400) of the epitaxial layer. The shielded gate trench metal-oxide-semiconductor field-effect transistor unit has a split gate structure. The two gates of the split gate structure (for example, the gate electrodes 230AG1 and 230AG2) are formed on opposite sidewalls of the electrode functioned as a field plate (which may also be called a source electrode, such as the first electrode 220F1). The split gate structure may further reduce the overall gate-to-drain capacitance (C_{gd}) and feedback capacitance (Cᵣₛₛ=C_{gd}) to improve overall power conversion efficiency of the shielded gate trench metal-oxide-semiconductor field-effect transistor (SGT MOSFET). The source electrode may reduce the gate-to-drain capacitance (C_{gd}) to improve the switching characteristics of the semiconductor device. In addition, the source electrode may result in a relatively uniform distribution of the electric field of the gate dielectric layer close to the bottom of the gate electrode and an increased breakdown voltage. Therefore, the reliability of the gate dielectric layer is improved. Furthermore, through the arrangement of the source electrode, the doping concentration of the epitaxial layer can be further increased in to reduce the on-resistance (Rₒₙₛₚ) of the shielded gate trench metal-oxide-semiconductor field-effect transistor unit.

In some embodiments, the top surfaces of the two gate electrodes that are separated from each other are lower than the top surface of the epitaxial layer and the top surface of the source electrode. In addition, the two gate electrodes are surrounded and covered by the gate dielectric layer. Furthermore, the top portion of the source electrode is exposed from the split gate structure. Therefore, the metal silicide (e.g., the metal silicide 246S) of the source contact (e.g., the source contact 250S) can be formed accurately on the top portion of the source electrode, the top surface of the source region, and the top surface of the pick-up doped region (i.e., the top surface of the epitaxial layer) without using the photolithography process with high-resolution photomasks. Accordingly, the source contact (e.g., the source contact 250S) can be formed to be accurately connected to the source electrode, the source region, and the pick-up doped region. The contact-trench overlay errors and the subsequent photoresist rework problem caused by conventional lithography processes can be avoided. The electrical uniformity and the reliability of the semiconductor device are improved. The fabrication cost of the high-resolution photomasks and the photolithography process can be saved as component density increasing.

In some embodiments, the ratio of the longitudinal thickness of a first portion of the gate dielectric layer between the gate electrode and the source electrode (e.g., the thickness T1 in the direction 320) to the lateral thickness of the second portion of the gate dielectric layer between the gate contact and the source contact (such as the thickness T2 in the direction 300) may be between 2 and 3 in order to provide a good electrical isolation between the source contact and the gate electrode and to facilitate the electrical connection between the source electrode and the source contact. In some embodiments, the source regions and pick-up doped regions of the shielded gate trench metal-oxide-semiconductor field-effect transistor unit are alternately arranged along the channel width direction (e.g., the direction 310), which can further reduce the lateral size of the source contact, thereby increasing the component density and reducing on-resistance of the component.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a silicon carbide substrate, wherein the silicon carbide substrate has a first region, a second region and a third region, and has a first conductivity type;
an epitaxial layer disposed on a top surface of the silicon carbide substrate, wherein the epitaxial layer has the first conductivity type;
a first electrode disposed in the epitaxial layer in the first region and extending in a first direction;
a split gate structure disposed in the epitaxial layer in the first region, wherein the split gate structure comprises:
a first gate electrode and a second gate electrode separated from each other and located on opposite sidewalls of the first electrode, wherein a top portion of the first electrode is exposed from the split gate structure; and
a source contact disposed on the epitaxial layer in the first region, wherein the source contact covers and is electrically connected to the top portion of the first electrode.

2. The semiconductor device as claimed in claim 1, wherein the split gate structure further comprises:
a gate dielectric layer disposed in the epitaxial layer in the first region and surrounding the first gate electrode and the second gate electrode, wherein the top portion of the first electrode protrudes from a top surface of the gate dielectric layer.

3. The semiconductor device as claimed in claim 2, wherein the gate dielectric layer has:
a first portion located between the first gate electrode and the first electrode; and
a second portion located between a first gate top surface of the first gate electrode and the top surface of the gate dielectric layer, wherein the first portion has a first thickness in a second direction, the second portion has a second thickness in the first direction, and a ratio of the second thickness to the first thickness is between 2 and 3.

4. The semiconductor device as claimed in claim 2, further comprising:
a well region located in the epitaxial layer, wherein the well region has a second conductivity type; and
source regions and pick-up doped regions located on the well region in the first region and close to a top surface of the epitaxial layer, wherein the source regions and the pick-up doped regions are alternately arranged along a third direction and have opposite conductivity types, and
wherein the source contact covers and is electrically connected to the source regions and the pick-up doped regions.

5. The semiconductor device as claimed in claim 4, wherein the source contact has a first sidewall and a second sidewall opposite to each other, the first sidewall is adjacent to the first electrode, and the second sidewall is adjacent to the source regions and the pick-up doped regions.

6. The semiconductor device as claimed in claim 4, wherein the source contact has a first lower surface, a second lower surface and a third lower surface, and wherein the first lower surface is connected to the top portion of the first electrode, the second lower surface is connected to the gate dielectric layer, and the third lower surface is connected to the source regions and the pick-up doped regions.

7. The semiconductor device as claimed in claim 6, wherein the first lower surface and the second lower surface are not coplanar with each other.

8. The semiconductor device as claimed in claim 6, wherein the first lower surface and the third lower surface of the source contact are formed of a first metal silicide.

9. The semiconductor device as claimed in claim 1, wherein the first electrode extends from below the first gate electrode and the second gate electrode to above the first gate electrode and the second gate electrode along the first direction and is inserted between the first gate electrode and the second gate electrode along a second direction.

10. The semiconductor device as claimed in claim 4, further comprising:
a second electrode disposed in the epitaxial layer in the second region and extending in the first direction, wherein the second electrode is electrically connected to the source contact;
a third gate electrode disposed in the epitaxial layer in the second region and connected to the split gate structure, wherein the third gate electrode extends from the opposite sidewall of the second electrode to cover a second electrode top surface of the second electrode and the top surface of the epitaxial layer;
a gate contact disposed on the epitaxial layer in the second region, wherein the gate contact covers and is electrically connected to the third gate electrode; and
a third electrode disposed in the epitaxial layer in the third region and extending in the first direction, wherein the third electrode is electrically connected to the source contact.

11. The semiconductor device as claimed in claim 10, further comprising:
an interlayer dielectric layer disposed in the epitaxial layer in the second region and the third region, wherein the top portion of the first electrode, the source regions, the pick-up doped regions and a top surface of the third gate electrode are exposed from the interlayer dielectric layer.

12. A method for forming a semiconductor device, comprising:
providing a silicon carbide substrate, wherein the silicon carbide substrate has a first region, a second region and a third region, and has a first conductivity type;
growing an epitaxial layer on a top surface of the silicon carbide substrate, wherein the epitaxial layer has the first conductivity type;
forming a first trench in the epitaxial layer in the first region along a first direction;
forming a first electrode in the first trench, wherein the first electrode extends in the first direction;
forming a first gate electrode and a second gate electrode separated from each other on opposite sidewalls of the first electrode;
entirely forming an interlayer dielectric layer;
completely removing the interlayer dielectric layer on a top surface of the epitaxial layer in the first region, so that a top portion of the first electrode is exposed from the remaining interlayer dielectric layer; and
forming a source contact on the epitaxial layer in the first region, wherein the source contact covers and is electrically connected to the top portion of the first electrode.

13. The method for forming a semiconductor device as claimed in claim 12, further comprising:
forming a well region in the epitaxial layer before forming the first trench, wherein the well region has a second conductivity type; and
forming source regions and pick-up doped regions on the well region in the first region after forming the first gate electrode and the second gate electrode, wherein the source regions and the pick-up doped regions are alternately arranged along a third direction and have opposite conductivity types.

14. The method for forming a semiconductor device as claimed in claim 13, wherein the source regions and the pick-up doped regions are exposed from the remaining interlayer dielectric layer before forming the source contact.

15. The method for forming a semiconductor device as claimed in claim 14, wherein forming the source contact comprises:
forming a first metal silicide on the top portion of the first electrode, the source regions and the pick-up doped regions.

16. The method for forming a semiconductor device as claimed in claim 12, further comprising:
forming a second trench and a third trench in the epitaxial layer in the second region and the third region respectively along the first direction during of the formation of the first trench;
forming a first conductive material, a second conductive material and a third conductive material in the first trench, the second trench and the third trench, wherein the first conductive material, the second conductive material and the third conductive material comprises the same material;
forming an oxide layer on the third conductive material; and
performing an oxidation process to form a gate dielectric layer in the first trench and the second trench, wherein forming the gate dielectric layer comprises partially oxidizing a first upper portion of the first conductive material and a second upper portion of the second conductive material, and the unoxidized first conductive material, the unoxidized second conductive material and the unoxidized third conductive material respectively form the first electrode, a second electrode and a third electrode.

17. The method for forming a semiconductor device as claimed in claim 16, wherein top surfaces of the first conductive material, the second conductive material and the third conductive material are located above the top surface of the epitaxial layer.

18. The method for forming a semiconductor device as claimed in claim 16, further comprising:
entirely forming an electrode material on the epitaxial layer after forming the first electrode, the second electrode and the third electrode, wherein the electrode material fills the first trench and the second trench; and
performing a patterning process to remove a portion of the electrode material above the epitaxial layer in the first region and the third region to form the first gate electrode and the second gate electrode in the first trench, and to form a third gate in the second trench.

19. The method for forming a semiconductor device as claimed in claim 18, wherein the top portion of the first electrode is located above a first gate top surface of the first gate electrode and a second gate top surface of the second gate electrode.

20. The method for forming a semiconductor device as claimed in claim 18, further comprising:
removing a portion of the interlayer dielectric layer on the third gate during the complete removal of the interlayer dielectric layer on the top surface of the epitaxial layer in the first region; and
forming a gate contact on the third gate during the formation of the source contact.
